(19) United States
(12) Patent Application Publication
(10) Pub. No.: US 2008/0157807 A1
(43) Pub. Date: Jul. 3, 2008

(54) PICKER FOR USE IN A HANDLER AND METHOD FOR ENABLING THE PICKER TO PLACE PACKAGED CHIPS

(76) Inventors: Heung-bok KIM, Cheonan-si (KR); Kwang-chun HWANG, Cheonan-si (KR); Beom-ho SHIN, Suwon-si (KR)

Correspondence Address: KED & ASSOCIATES, LLP, P.O. Box 221200, Chantilly, VA, 20153-1200, US

(21) Appl. No.: 11/962,310

(22) Filed: Dec. 21, 2007

(30) Foreign Application Priority Data
Dec. 27, 2006 (KR) 10-2006-0134432

(51) Int. Cl. G01R 31/26

(52) U.S. Cl. 324/765

(57) ABSTRACT

Provided is a picker for use in a handler, including at least one picker base, a row of nozzles provided to each of the picker base, and a detecting unit, provided to one side of each of the nozzle, for detecting if a packaged chip exists in a carrying hole on a user tray. The picker is capable of detecting if the packaged chip exists in a first row of the carrying holes on the user tray. And the picker is capable of placing the packaged chips into the first row of the carrying holes on the user tray and at the same time detecting if the packaged chip exists in a second row of the carrying holes on the user tray, when existence of the packaged chip is not detected on the first row of the carrying holes on the user tray.

### BACKGROUND OF THE INVENTION

1. Field of the Invention

The present invention relates to a picker for picking up, transferring and placing packaged chips, for use in a handler, and more particularly to a picker for picking up, transferring and placing packaged chips, for use in a handler, capable of placing the packaged chips into a row of carrying holes on an user tray and at the same time detecting existence of any packaged chip in a next row of carrying holes on the user tray.

2. Description of the Background Art

At the conclusion of a packaging process, a handler puts packaged chips through a series of environmental, electrical, and reliability tests. These tests vary in type and specifications, depending on the customer and use of the packaged devices. The tests may be performed on all of the packages in a lot or on selected samples.

The handler places packaged chips into a test tray and supplies the test tray to a tester. The tester includes a test board with a plurality of sockets, performing an electrical test on the packaged chips. The packaged chips come in contact with the sockets of the test board for the electrical test. The handler places the packaged chips into a test tray, i.e. a jig and enables the packaged chips contained in the test tray to get in contact with the sockets of the test board. The handler grades the packaged chips according to the test results of the packaged chips. The handler removes packaged chips from a user tray and places them into carrying holes on the test tray. The handler transfers the test tray to the tester. (This is referred as to “a loading operation”). The handler removes tested packaged chips from the carrying holes on the test tray and transfers them to a user tray (This is referred as to “an unloading operation”)

The handler includes a loading stacker where the user trays are stacked, a unloading stacker where the user trays are stacked each of which are intended to contain the tested packaged chips of the same grade, an exchanging site where a test tray containing packaged chips intended for the electrical test stays before being transferred to the tester, a loading picker transferring the packaged chips intended for the electrical test, from the loading stacker to the test tray, and an unloading picker transferring the tested packaged chips from the test tray to the unloading stacker.

The loading picker picks up the packaged chips intended for the electrical test from the loading stacker to place them into the test tray staying at the exchanging site. The test tray containing the packaged chips intended for the electrical test is transferred to the tester. The test tray, after the packaged chips are tested, is transferred to an unloading unit. The unloading picker picks up the tested packaged chips from the test tray to transfer them to the unloading stacker. The tested packaged chip, after graded, is placed into a corresponding user tray staying in the unloading stacker.

A conventional picker has to check if all carrying holes on the user tray are empty before placing the tested packaged chips into them. When all carrying holes on the user tray are found to be empty, the picker begins to pick up the tested packaged chip from the test tray, transfer it and place it into the carrying holes on the user tray.

This requires the conventional picker to spend considerable time in picking up all tested packaged chips from the test tray, transferring them and placing them into the carrying holes on the user tray.

### BRIEF DESCRIPTION OF THE INVENTION

Therefore, an object of the present invention is to provide a picker for use in a handler, capable of placing packaged chips into a row of carrying holes on an user tray and at the same time detecting existence of any packaged chip in a next row of carrying holes on the user tray.

According to an aspect of the present invention, there is provided a picker for use in a handler, including a picker base, a nozzle unit, and a detecting unit. The nozzle unit is provided to the picker base. At least one nozzle is provided to the nozzle unit. Two or more nozzles may be provided to the nozzle unit, to be arranged in a column. The detecting unit is positioned behind each of the nozzles. When the nozzles places packaged chips into a row of carrying holes on a user tray, the detecting unit detects existence of any packaged chip in a next row of carrying holes on the user tray.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a plane view illustrating a handler equipped with a picker according to an embodiment of the present invention;

FIG. 2 is a perspective view illustrating the picker according to the embodiment of the present invention;

FIGS. 3 and 4 are exploded views illustrating a detecting unit of the picker of FIG. 2;

FIG. 5 is a perspective view illustrating how the detecting unit of FIG. 4 operates, as an example; and

FIGS. 6 and 7 are perspective views illustrating how the picker of FIG. 2 operates as an example;

### DETAILED DESCRIPTION OF THE INVENTION

Reference will now be made in detail to the preferred embodiments of the present invention, examples of which are illustrated in the accompanying drawings.

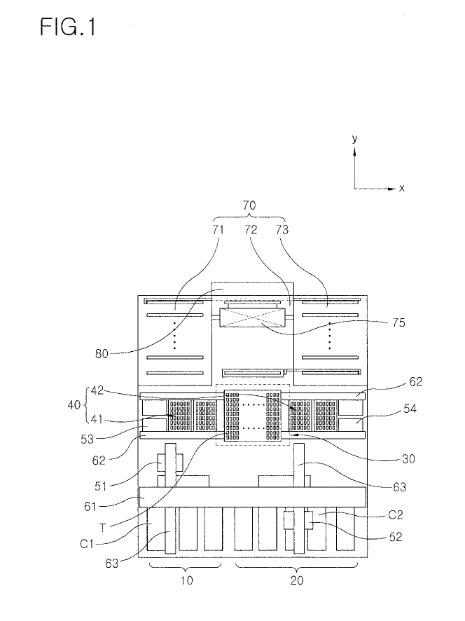

FIG. 1 is a plane view illustrating a handler equipped with a picker for picking up, transferring and placing a packaged chip, according to an embodiment of the present invention. As shown in FIG. 1. the handler includes a loading stacker 10, an unloading stacker 20, an exchanging site 30, first, second, third, and fourth pickers 51, 52, 53, and 54, and a test unit 70.

User trays C1, each of which contains packaged chips intended for an electrical test, stay in the unloading stacker 110. The unloading stacker 20 are adjacent to the loading stacker 10. User trays C2 stay in the unloading stacker 20. Each tray C2 is intended to contain tested packaged chips of the same grade according to test results.

A test tray T stays in the exchanging site 30. The packaged chips that are to be tested are supplied from the loading stacker 10 to the exchanging site 30, and loaded onto the test tray T. The tested packaged chips are unloaded from the test tray in the exchanging site 30 and transferred to the unloading stacker 20.

A buffer unit 40 is provided adjacent to both sides of the exchanging site 30. The packaged chips temporarily stay in the buffer unit 40. The buffer unit 40 includes a loading buffer unit 41 and an unloading buffer unit 42. The buffer unit 40 can be moved backward and forward in the X-axis direction, when the third and fourth pickers 53 and 54 are determined to be moved only in the Y-axis direction.

The first, second, third and fourth pickers 51, 52, 53, and 54 are provided to be moved over the exchanging site 30, the loading stacker 10, and the unloading stacker 20. The first picker 51 is moved backward and forward between the loading stacker 10 and the loading buffer unit 41 to pick up, transfer and place the packaged chips. The second picker 52 is moved backward and forward between the unloading stacker 20 and the unloading buffer unit 42 to pick up, transfer and place the packaged chip. The first picker 51 is provided to a first gantry 61, to be movable in the X-axis direction. The second picker 52 is provided to a second gantry 63, to be movable in the Y-axis direction.

The third picker 53 is moved backward and forward between the loading buffer unit 41 and the exchanging site 30 to pick up, transfer, and place the packaged chips. The fourth picker 54 is moved backward and forward between the unloading buffer unit 42 and the exchanging site 30 to pick up, transfer, and place the packaged chips. The third and fourth pickers 53 and 54 are provided to a third gantry 62, to be movable backward and forward in the X-axis direction, when the buffer unit 40 and the test tray T are enabled to be moved backward and forward in the Y-axis direction.

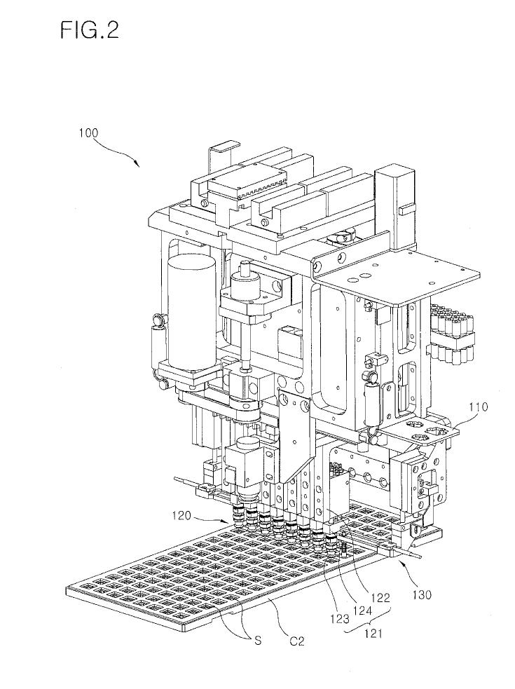

A configuration for the second picker 52 may be the same as that for a picker 100, as shown in FIG. 2. The picker 100 according to the embodiment of the present invention is later described.

The test tray T, containing the packaged chips intended for the electrical test, is transferred from the exchanging site 30 to the test unit 70. Then, a tester in the test unit 70 performs tests on the packaged chips intended for the electrical test. The test unit 70 provides environments where the packaged chips are tested at extremely high or low temperature as well as at room temperature.

The test unit 70 includes a first chamber 71, a second chamber 72, a third chamber 73. The test tray T containing the packaged chips goes through the first, second, and third chambers, in this order. In the first chamber 71, the packaged chips contained in the test tray T are heated to extremely high temperature or cooled to extremely low temperature. In the second chamber 72, the extremely high-heated or extremely low-cooled packaged chips are tested by the tester. The second chamber 72 has a test site where an upright-positioned test board 80 of the tester comes in contact with the packaged chips. The test board 80 has a plurality of sockets. The packaged chips contained in the test tray T are connected to the sockets of the test board 80.

The second chamber 73 has a pushing unit 75. The pushing unit 75 pushes the test tray T toward the test board 80 to connect the packaged chips to the sockets. Other pushing unit established on the wall of a the second chamber pulls the test tray T from the test board 80 to separate the packaged chips from the sockets. In the third chamber 73, the extremely high-heated or extremely low-cooled packaged chips are cooled or heated to room temperature, respectively, after testing in the second chamber 72.

The packaged chips, after tested in the test unit 70, are transferred back to the exchanging site 30. The second picker 52 picks up the tested packaged chips from the test tray. During transferring, the second picker 52 grades the tested packaged chip according to the test result. Then, the second picker 53 places the tested packaged chip into the corresponding user tray C2 staying in the unloading stacker 20.

A configuration for the second picker 52 may be the same as that for the picker 100 according to the embodiment of the present invention, as shown in FIG. 2.

As shown in FIG. 2, the picker 100 according to the embodiment of the present invention includes a picker base 110, a nozzle unit 120, and a detecting unit 130.

The picker base 110 supports the nozzle unit 120 and the detecting unit 130. The picker base 110 is provided to the first and second gantries 61 and 62, to be movable backward and forward in the X-axis and Y-axis directions, respectively. The nozzle unit 120 picks up the tested packaged chip from the unloading buffer unit 42 and places it into a carrying hole S of the corresponding user tray C2. The carrying holes S, where the packaged chips are placed, are arranged in rows and columns in the user tray C2. The nozzle unit 120 includes two or more nozzle assemblies 121. The nozzle assemblies arranged in one row are provided to the picker base 110.

The detecting units 130 may be arranged in two or more rows when the nozzle assemblies 121 are arranged in two or more rows. In this case, at least one row of detecting units 130 is provided behind one row of nozzle assemblies 121.

The nozzle assembly 121 includes a nozzle 123. The nozzle 123 is provided on a lower section of a body 122 of the nozzle assembly 121. The packaged chip is sucked against and released from an orifice of the nozzle 123. That is, the nozzle 123 sucks the packaged chip by applying negative air pressure and releases the packaged chip by applying positive air pressure. The nozzle 123 ascends and descends with respect to the body 122 of the nozzle assembly 121, when picking up and placing the packaged chip, respectively. An elevating apparatus includes a carriage 124 and an air-supplying unit. The nozzle 123 is fixed to the carriage 124. The carriage 124 is provided to the body 122 of the nozzle assembly 121, to be ascendable and descendable. The air-supplying unit moves the carriage 124 up and down by controlling application of air pressure.

The nozzle assemblies 121 are provided to the picker base 110 in a manner to enable a distance-adjusting unit to adjust a distance between the nozzle assemblies 121. Thus, the distance between the nozzles 123 can be adjusted depending upon a distance between the carrying holes on the tray C2. This enables the nozzle unit 120 to pick up and place one row of packaged chips from the unloading buffer unit 42 and into the user tray C2.

Before one row of packaged chips are placed into a corresponding row of carrying holes S of the user tray C2, the detecting unit 130 detects if any carrying hole S in a next row of the user tray C2 is empty. The detecting unit 130 is positioned behind each of the nozzle assembly 121.

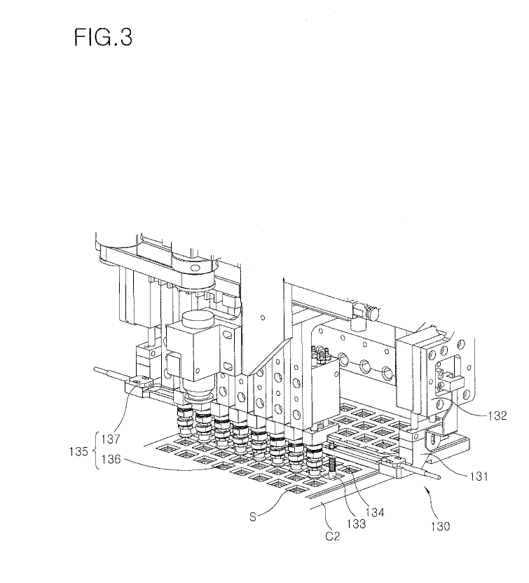

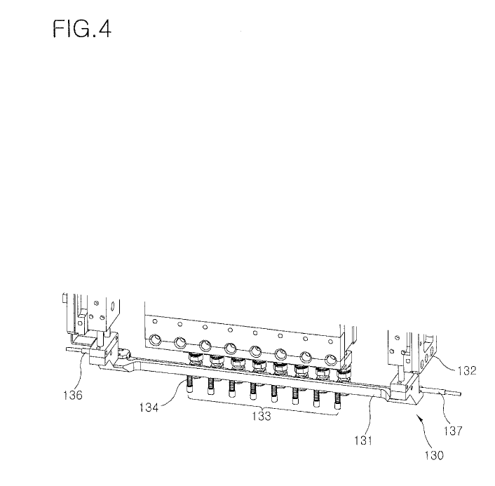

The detecting unit 130, as shown in FIGS. 3 and 4, includes a detecting bracket 131, an actuator 132, pins 133, elastic members 134, and a sensor 135.

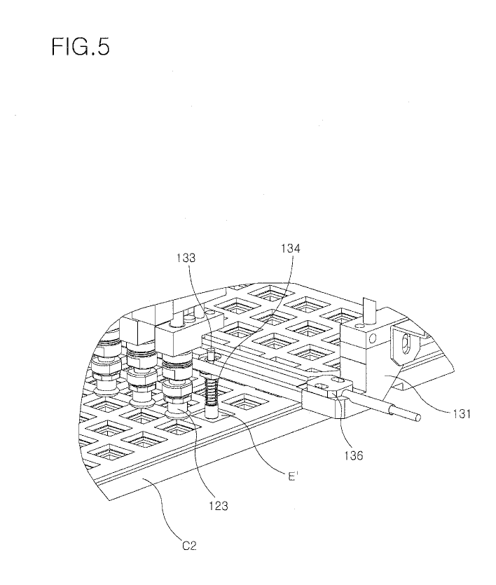

The detecting bracket 131 is provided to the picker base 110, to be ascendable and descendable. The actuator 132 moves the detecting bracket 131 up and down. The actuator 132 moves down the detecting bracket 131, as shown in FIG. 5, when detecting if any carrying hole S of the user tray C2 is empty. The actuator 132 moves up the detecting bracket 131 after detecting if any carrying hole S in a next row of the user tray C2 is empty. The actuator 132 may be an air cylinder.

The pins 133 are provided to the detecting bracket 131, to be movable upward. The pin 133 protrudes downward from the detecting bracket 131.

A distance between the pins 133 is the same as that between the carrying holes S of the user tray C2. Thus, the pin 133 is positioned at each of the carrying holes S of the user tray C2 which are arranged in a row. A distance between the pin and the nozzle assembly 121 is the same as that between the carrying holes S of the user tray C2 which are arranged in a column. Thus, when a row of nozzles 123 are positioned at a row of carrying holes S of the user tray C2, the pin 133 is made to be positioned at each of carrying holes in a next row.

When descending and then coming in contact with the packaged chip E′ remaining in the carrying hole S of the user tray C2, the pin 133 ascends from the detecting bracket 131.

At this point, the elastic member 134 applies an elastic force to the pin 133 in a downward direction. Accordingly, when not being in contact with the packaged chip E′ in the carrying hole S, the pin 133 does not move original position.

The sensor 135 detects if the pin 133 ascends from the detecting bracket 131. Ascension of the pin 133 occurs when the corresponding carrying hole is not empty.

If ascension of any of the pins 133 is recognized when the pins 133 are all moved down into the carrying holes S of the user tray C2, each pin into each carrying hole, it is recognized that the carrying holes S of the user tray C2 are all not empty. Action is taken to remove the packaged chip remaining in the carrying hole S of the user tray C2. The detecting unit 130 may be controlled to detect if any packaged chip remains in a row of carrying holes next to the row of carrying holes all of which are not empty.

The sensor 135 may include an emitting part 136 and a receiving part 137. The emitting and receiving parts 136 and 137, which are provided to be opposite to each other, are located at a position to track motion of the pins 133. The emitting part 136 emits light toward the receiving part 137. The receiving part 137 receives the light emitted from the emitting part 136 when the ascending pin 133 does not block the light. When this is done, all carrying holes S of the user tray C2 are recognized as being empty.

When ascending, the pin 133 blocks the light emitted from the emitting part 136, thus preventing the receiving part 137 from receiving the light. When this is done, at least one carrying hole S of the user tray C2 is recognized as being occupied. And, the pick-up and placing operation of the picker is stopped.

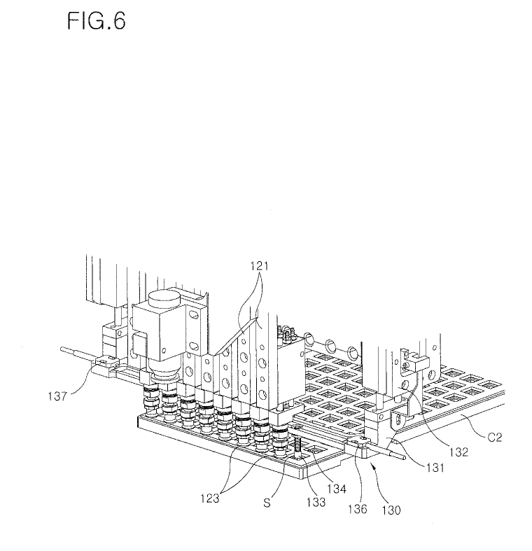

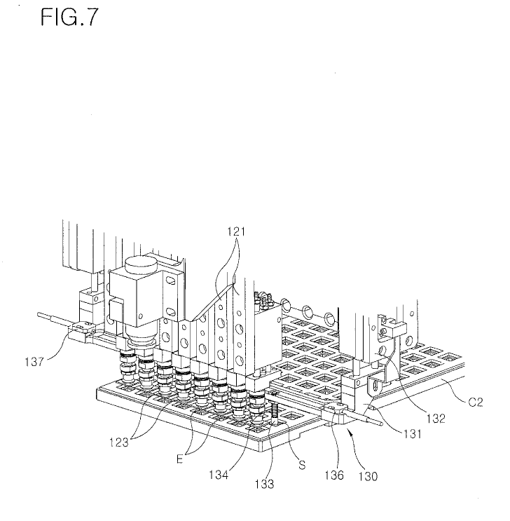

Referring to FIGS. 6 and 7, operation of the picker 100 equipped with the detecting unit 130 is now described.

The picker 100, as shown in FIG. 6, is moved to the user tray C2. And, the picker 100 detects if a first row of carrying holes S of the user tray C2 are empty, using the detecting unit 130.

When the detecting unit 130 recognizes all carrying holes S of the user tray C2 as being empty, the picker 100 picks up the packaged chips E from the unloading buffer unit 42 and transfers them to the user tray C2, using the nozzle unit 120. Then, the picker 100 places the packaged chips E into a first row of carrying holes S of the user tray C2. At this point, the picker 100 detects if a second row of carrying holes S of the user tray C2 are all empty, using the detecting unit 130.

When the detecting unit 130 recognizes the second row of carrying holes S of the user tray C2 as being empty, the picker picks up the packaged chips from the unloading buffer unit 42 and transfer them to the user tray C2. Then the picker 100 places the packaged chips into the second row of carrying holes S of the user tray C2. At this point, the picker 100 detects if a third row of carrying holes S of the user tray C2 are all empty, using the detecting unit 130. Like this, a cycle of picking up, transferring, and placing the packaged chips is conducted in an exact and repeatable manner until all packaged chips in the unloading buffer unit 42 are placed into the carrying holes on the user tray C2.

When the detecting unit 130 recognizes the second row of carrying holes S of the user tray C2 as being occupied, the picker proceeds to pick up the packaged chip existing in the second row carrying holes S of the user tray C2. This is done to confirm the existence of the packaged chip in the user tray C2. The actual pick-up of the packaged chip by the picker 100 enables the handler to stop the pick-up and placing operation and to generate an error signal to alert an operator to the status of the process.

A control unit controls the detecting unit 130 that detects if the packaged chip exits in the second row of carrying holes S of the user tray C2. When the second row of carrying holes S of the user tray C2 is empty, the control unit instructs the picker either to proceed to place the packaged chips into the second row of the carry holes S, or to stop the pick-up and placing operation and generate the error signal, depending upon an outcome of the detecting operation.

The picker 100 according to the present invention places the packaged chips E into a row of carrying holes S of the user tray C2 and at the same time detects if any of the packaged chips E remains in a next row of carrying holes on the same user tray C2. Thus, the picker 100 places the packaged chips into the user trays C2 more speedily than the conventional picker which is required to check if any of the packaged chips remains in the corresponding carrying holes on the user trays C2 before placing the packaged chips into the corresponding carrying holes on the user trays C2.

The picker 100 according to the present invention may be employed in placing the packaged chips E onto the loading buffer unit 41 and into the test tray T.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalents of such metes and bounds are therefore intended to be embraced by the appended claims.

What is claimed is:

1. A picker for use in a handler, comprising:
at least one picker base;
a row of nozzles provided to each of the picker base; and
a detecting unit, provided to one side of each of the nozzle, for detecting if a packaged chip exists in a carrying hole on a user tray.

2. The picker for use in a handler according to claim 1, wherein the detecting unit comprises:
a detecting bracket, provided to the picker base, to be movable up and down an actuator for moving up and down the detecting bracket;
a plurality of pins, provided to the detecting bracket, to be movable up and down’
a sensor for sensing if the pin is moved up from the detecting bracket; and
a control unit for controlling operation of the picker in response to a signal from the sensor.

3. The picker for use in a handler according to claim 2, wherein the pins are arranged in at least one row which is parallel to the row in which the nozzles are arranged

4. The picker for use in a handler according to claim 2, further comprising an elastic member for returning the ascending pins to their original position.

5. The picker for use in a handler according to claim 3, wherein the pins are spaced at the same regular intervals as the carrying holes on the user tray into each of which the packaged chips is placed.

6. The picker for use in a handler according to claim 2, wherein the sensor comprises:
an emitting part emitting light; and
a receiving part receiving the light from the emitting part,
and wherein ascension of the pin from the detecting bracket is detected when the pin blocks the light emitted from the emitting part.

7. The picker for use in a handler according to claim 6, wherein the pin is moved up from the detecting bracket when coming in contact with the packaged chip existing in the carrying hole on the user tray.

8. The picker for use in a handler according to claim 2, wherein the actuator is an air-pressure cylinder.

9. The picker for use in a handler according to claim 1, wherein the user trays, each of which is to contain the packaged chips of the same grade, stays in an unloading stacker

10. The picker for use in a handler according to claim 1, wherein a distance between the nozzles is adjusted by a distance-adjusting unit.

11. A method for enabling a picker to place packaged chips into carrying holes on a user tray, the picker for use in a handler, comprising at least one picker base, at least a row of nozzles provided to each of the picker base, and a detecting unit, provided to one side of each of the nozzles, for detecting if the packaged chip exists in the carrying hole on the user tray, the method comprising steps of:
enabling the detecting unit to detect if the packaged chip exists in a first row of the carrying holes on the user tray; and
allowing the plurality of the nozzles to place the packaged chips into the first row of the carrying holes on the user tray and at the same time enabling the detecting unit to detect if the packaged chip exists in a second row of the carrying holes on the user tray, when the detecting unit does not detect existence of the packaged chip on the first row of the carrying holes on the user tray.

12. The method according to claim 11, further comprising picking up the existing packaged chip in the event of the existence of the packaged chip in the first row of the carrying holes on the user tray.

13. The method according to claim 11, further comprising performing a pick-up operation to ensure existence of the packaged chip in the first row of the carrying holes in the event of the existence of the packaged chip in the first row of the carrying holes on the user tray
